(19) United States
(12) Patent Application Publication
(10) Pub. No.: US 2005/0263071 A1
(43) Pub. Date: Dec. 1, 2005

(54) Apparatus and system for manufacturing a semiconductor

(75) Inventors: Shigeru Yagi, Kanagawa (JP); Nobuyuki Torigoe, Kanagawa (JP)

Correspondence Address: MORGAN LEWIS & BOCKIUS LLP, 1111 PENNSYLVANIA AVENUE NW, WASHINGTON, DC, 20004, US

(73) Assignee: FUJI XEROX CO., LTD.

(21) Appl. No.: 11/006,578

(22) Filed: Dec. 8, 2004

(30) Foreign Application Priority Data
Jun. 1, 2004 (JP) 2004-163892

(51) Int. Cl. C23C 16/00

(52) U.S. Cl. 118/715

(57) ABSTRACT

The present invention provides an apparatus for manufacturing a semiconductor including: a reactor; a substrate holder for supporting a substrate; a primary gas supply unit for supplying a primary gas to the reactor; a secondary gas supply unit for supplying a secondary gas to the reactor; a first plasma generator for activating the primary gas to produce an activated gas; and a second plasma generator for activating a gas flow which includes the activated gas, wherein the gas flow is blown substantially perpendicularly onto a surface of the substrate on which surface a film is to be formed, and the second plasma generator discharges toward the center of the gas flow. The present invention also provides a system for manufacturing a semiconductor including the apparatus described above and a unit for moving the substrate holder.

CROSS-REFERENCE TO RELATED APPLICATION

This application claims priority under 35 USC 119 from Japanese Patent Application No. 2004-163892, the disclosure of which is incorporated by reference herein.

### BACKGROUND OF THE INVENTION

1. Field of the Invention

The present invention relates to an apparatus for manufacturing a semiconductor by forming a semiconductor thin film on a substrate, and a system for manufacturing a semiconductor that includes the apparatus for manufacturing a semiconductor.

2. Description of the Related Art

As materials that emit light having wavelengths in blue and ultraviolet regions, for application in photoelectric devices, semiconductors including compounds with elements of Group III (Group 13 in a revised edition of Inorganic Chemistry Nomenclature in 1989 by IUPAC (International Union of Pure and Applied Chemistry))-Group V (Group 15 in the revised edition of Inorganic Chemistry Nomenclature) that have a wide bandgap, such as AlN, AlGaN, GaN, GaInN and InN, are attracting attention.

A molecular-beam epitaxy (MBE) method and a metal-organic chemical vapor deposition (MOCVD) method are mainly used as a method for growing a thin film. In the MOCVD method, raw materials transported in a vapor phase are reacted in a chemical reaction, and the resultant semiconductor is deposited on a substrate. In the method, formation of an extremely thin film and control of mixed-crystal ratio can be easily performed by controlling the flow rate of gas supplied at the time of film deposition. Since the MOCVD method can realize uniform crystal growth on a large substrate, in principle, the MOCVD method is an industrially important method.

However, the temperature of a substrate necessary for growth of high-quality GaN crystal in the MOCVD method is within the range of 900 to 1200° C., which limits the type of material for the substrate. Moreover, there is a limitation to the degree of freedom in device configuration for production, since a semiconductor is laminated on an electrode in the method. However, a remote plasma MOCVD method is effective for lowering the growth temperature. In the remote plasma MOCVD method, raw material gases are decomposed by plasma oscillation using microwave or radiofrequency waves, and a gaseous organometallic compound is introduced into the remote plasma and the resultant semiconductor is deposited on a substrate.

In the remote plasma MOCVD method, films are formed by manufacturing devices that have multiple plasma generators. This is in order to independently control factors which are important for producing mixed crystals and multi-layer films, such as the type, the pressure and the flow rate of carrier gases. In this case, the plasma generators are disposed in the device as described above, and supplementary agents such as hydrogen and the like are introduced from one direction. Thereby, contamination of carbon into a semiconductor film can be decreased by the reducing effect of hydrogen radicals, and film defects can be suppressed producing high-quality thin films.

However, in a conventional apparatus for manufacturing a semiconductor which has multiple plasma generators, the plasma generators are set in directions different to the direction perpendicular to a surface of the substrate on which surface a film is to be formed (film-forming surface) (see Japanese Patent Application Laid-Open (JP-A) No. 10-79348). Therefore, each gas activated by a plasma generator is introduced into a reactor from a direction different to a direction perpendicular to the surface of the substrate, and the flow of gas in the reactor varies due to the difference of the flow rates of the activated gases. Accordingly, the thickness of portions of the resultant film formed depends on their position on the substrate surface. Therefore, a complicated device including a mechanism for rotating the substrate is required so as to make the thickness of the film deposited on the substrate uniform.

When a film is deposited by introducing a raw material gas to react with a primary raw material gas (secondary raw material gas) into a raw material gas activated by a plasma generator (primary raw material gas, the type of the secondary raw material gas used depends on the type of plasma generator. Also the primary and secondary reactive gases activated by their corresponding plasma generators are insufficiently mixed in the vicinity directly above the film-forming surface of the substrate, and hence the composition of portions of the thin film formed on the substrate depends on their position on the substrate surface. Even a mechanism for rotating the substrate cannot necessarily prevent such unevenness of composition in-plane of the film.

For these reasons, optimum film formation can be conducted only on a small area of the substrate, and a film having uniform composition and thickness cannot be formed on a large substrate.

In order to solve such problems, an apparatus for manufacturing a semiconductor was proposed in which gases activated by plasma generators are blown substantially perpendicularly onto the film-forming surface of a substrate (see JP-A No. 2001-77028). However when a large semiconductor thin film is formed, whilst the apparatus can satisfy the quality requirements for uniformity of the thickness of film in-plane, it may not meet the severe requirements for uniformity of composition in-plane of the film.

Therefore, there is a need for an apparatus for manufacturing a semiconductor which: can form a semiconductor thin film having uniform composition and thickness on a large substrate; and does not have a complicated structure such as one having a mechanism for rotating the substrate. Moreover, there is a need for a system for manufacturing a semiconductor which uses such an apparatus.

### SUMMARY OF THE INVENTION

In order to address the above-described needs, the inventors have conducted a keen examination of the problems of unevenness of in-plane film quality which may occur in apparatuses for manufacturing semiconductors where gases activated by plasma generators are blown substantially perpendicularly onto a film-forming surface of a substrate.

Although various factors may cause unevenness of in-plane quality of the film, one of the contributing factors is thought to be unevenness, in a direction parallel to the surface, in conditions of activation of the gas flow immediately prior to reaching the film-forming surface of a substrate.

In the apparatus for manufacturing a semiconductor disclosed in JP-A No. 2001-77028, the direction along which a plasma generator (unit for electrically discharging a perpendicularly blown gas flow) electrically discharges a gas flow, activated by another plasma generator and blown substantially perpendicularly onto a film-forming surface of a substrate (perpendicular gas flow), is equal to the direction of the gas flow. In addition, the electrical discharge portion of the unit for electrically discharging a perpendicularly blown gas flow is arranged so as to occupy part of a plane facing the film-forming surface of the substrate.

Therefore, the inventors thought that uneven film quality is caused by the electrical discharge not reaching fully the central portion of the gas flow. However, when the discharge unit is disposed such that the central portion of the gas flow is sufficiently electrically discharged, the electrical discharge unit obstructs the gas flow.

In addition, since the electrical discharging unit is disposed in the main stream of the gas flow, product adheres to and deposits on the electrical discharging unit, and the deposit may fall from the discharging unit and contaminate the reactor and/or the film-forming surface of the substrate. It is hence necessary to frequently clean the reactor so as to prevent such contamination. In addition, when such an apparatus is used for continuous production, much non-production time is needed for frequent cleaning, start-ups after the cleaning and the like, and productivity therefore deteriorates.

The inventors thought that it is important to dispose a plasma generator in such a way as to enable the gas flow to be uniformly activated in a direction parallel to the film-forming surface of a substrate. In addition, from the viewpoint of contamination prevention, the inventors thought that it is important to dispose the plasma generators so as not to obstruct the gas flow and have devised the invention.

A first aspect of the invention provides an apparatus for manufacturing a semiconductor including: a reactor; a substrate holder for supporting a substrate; a primary gas supply unit for supplying a primary gas to the reactor; a secondary gas supply unit for supplying a secondary gas to the reactor; a first plasma generator for activating the primary gas to produce an activated gas; and a second plasma generator for activating a gas flow which includes the activated gas; wherein the gas flow is blown substantially perpendicularly onto a surface of the substrate on which surface a film is to be formed, and the second plasma generator electrically discharges toward the center of the gas flow.

A second aspect of the invention provides a system for manufacturing a semiconductor comprising: a reactor; a substrate holder for supporting a substrate; a unit for moving the substrate holder; and at least two apparatuses for manufacturing a semiconductor each comprising a primary gas supply unit for supplying a primary gas to the reactor, a secondary gas supply unit for supplying a secondary gas to the reactor, a first plasma generator for activating the primary gas to produce an activated gas, and a second plasma generator for activating a gas flow which includes the activated gas wherein the gas flow is blown substantially perpendicularly onto the film-forming surface of the substrate, and the second plasma generator discharges toward the center of the gas flow.

### BRIEF DESCRIPTION OF THE DRAWINGS

Preferred embodiments of the invention will be described in detail on the basis of the following figures, wherein:

FIG. 1 is a front view showing the schematic configuration of an embodiment of an apparatus for manufacturing a semiconductor of the invention;

FIG. 2 is a front view showing the schematic configuration of another embodiment of the apparatus for manufacturing a semiconductor of the invention;

FIGS. 3A to 3C are cross-sectional views, showing the shapes and arrangements of plate-shaped electrodes (second plasma generators), obtained by cutting the electrodes along planes parallel to the direction of the gas flow perpendicularly blown onto a film-forming surface of a substrate;

FIGS. 4A to 4C are plan views schematically showing the shapes and arrangements of plate-shaped electrodes (second plasma generators).

### DETAILED DESCRIPTION OF THE INVENTION

Apparatus for Manufacturing Semiconductor

An apparatus for manufacturing a semiconductor of the invention includes: a reactor; a substrate holder for supporting a substrate; a primary gas supply unit for supplying a primary gas to the reactor; a secondary gas supply unit for supplying a secondary gas to the reactor; a first plasma generator for activating the primary gas to produce an activated gas; and a second plasma generator for activating a gas flow which includes the activated gas; wherein the gas flow is blown substantially perpendicularly onto the film-forming surface of the substrate, and the second plasma generator electrically discharges toward the center of the gas flow.

Therefore, the apparatus of the invention can form a semiconductor thin film of a uniform in-plane composition and a uniform in-plane thickness on a large substrate without using a complicated unit such as a mechanism for rotating the substrate.

Moreover, the second plasma generator of the apparatus of the invention electrically discharges toward the center of the gas flow. Accordingly, the apparatus of the invention can make the state of activation of a portion of the gas flow immediately before the surface of the substrate more uniform, in a direction parallel to the surface, than an apparatus for manufacturing a semiconductor having a conventional plasma generator for activating a gas flow blown perpendicularly onto a film-forming surface of a substrate. Therefore, in-plane uniformity of the composition of the film formed on a substrate can be further improved.

There are no particular limitations to the configuration and position of the second plasma generator, as long as the second plasma generator can electrically discharge toward the center (central axis) of the gas flow. However, the second plasma generator is particularly preferably disposed away from the main stream of the gas flow so that the second plasma generator does not obstruct the gas flow.

When the second plasma generator is disposed in the main stream, product may adhere to and deposit on the second plasma generator, and the deposit may fall from the second plasma generator and contaminate the inside of the reactor and the film-forming surface of the substrate. In addition, when continuous production is performed with an apparatus having such a plasma generator, much non-production time may be required for frequent cleaning and start-up of the apparatus after cleaning, and productivity may therefore deteriorate.

In order to well balance various practical requirements, such as to improve in-plane uniformity of the composition of a film formed on a substrate, prevent contamination, improve productivity and simplify the device structure, the second plasma generator preferably has a configuration and arrangement as symmetrical with respect to the center of the gas flow as possible. The second plasma generator meeting such requirements is preferably a cylindrical electrode which surrounds the main stream of the gas flow and which has an electrical discharge surface arranged substantially parallel to the direction of the gas flow.

The primary gas supply unit is preferably disposed substantially perpendicular to the film-forming surface of the substrate.

The secondary gas supply unit may be disposed at any position from which gas can be introduced to the reactor, as long as the secondary gas supply unit is disposed on an upstream side of the substrate holder, which upstream side is opposite to an exhaust vent from which gas in the reactor is exhausted. For example, the secondary gas supply unit can be directly joined to the reactor or joined to a gas flow passage such as a gas introduction pipe connected to the reactor.

Whilst there is a need for at least one gas supply unit, of multiple gas supply units, to supply raw material gas to the reactor, one or more other gas supply unit(s) which supply auxiliary gas to the reactor may, or may not, be used as required.

The secondary gas supply unit is preferably disposed at a position described below so as to be able to: improve controllability of various physical properties such as electric characteristics; and meet various conditions necessary for production of a semiconductor thin film having complicated composition, and control of the composition of a film in the direction of film thickness.

When the secondary gas supply unit supplies one or more raw material gases, the secondary gas supply unit is preferably disposed such that the raw material gas joins the activated gas between a region where the first plasma generator activates the primary raw material gas and a region in which the second plasma generator activates the gas flow.

When the secondary gas supply unit supplies one or more auxiliary gas, the secondary gas supply unit is preferably disposed to enable the auxiliary gas to join the gas flow in a region where the second plasma generator activates the gas flow blown perpendicularly onto the substrate, and/or in a region adjacent to and upstream of the above region.

In this case, it is particularly preferable to dispose the secondary gas supply unit outside of the region where the second plasma generator activates the gas flow, so as to prevent adhesion, deposition of product and contamination caused by falling deposits.

When the primary and/or secondary gas supply units are used to supply at least one raw material, they preferably have one or more nozzles (gas introduction pipes) provided with a flow rate adjuster. When there is more than one nozzle supplying raw material gas, it is preferable that each nozzle has a flow rate adjuster. In this way, conditions for forming a film can be more precisely controlled.

The raw material gas cannot be strictly distinguished from the auxiliary gas in the invention. However, the raw material gas generally means a gas containing a component essential to form the basic skeleton of a semiconductor or containing a main component of the basic skeleton. The raw material may also include a component modifying the basic skeleton of the semiconductor, or may also function as a carrier gas.

On the other hand, auxiliary gas means a gas that does not contain a component essential to form the basic skeleton of the semiconductor nor contain a main component of the basic skeleton. For instance, the auxiliary gas may: contain only a component modifying the basic skeleton; function as only a carrier gas; have only a function for controlling the discharged state; or function as at least two of these gases.

For instance, when a semiconductor thin film is made of a nitride semiconductor, raw material gases are organometallic gases such as trimethyl gallium, trimethyl indium or the like, and nitrogen gas, and auxiliary gase is hydrogen gas, helium gas, argon gas or the like.

Embodiments of Apparatus for Manufacturing Semiconductor

Next, embodiments of the apparatus for manufacturing a semiconductor of the invention will be described with reference to drawings.

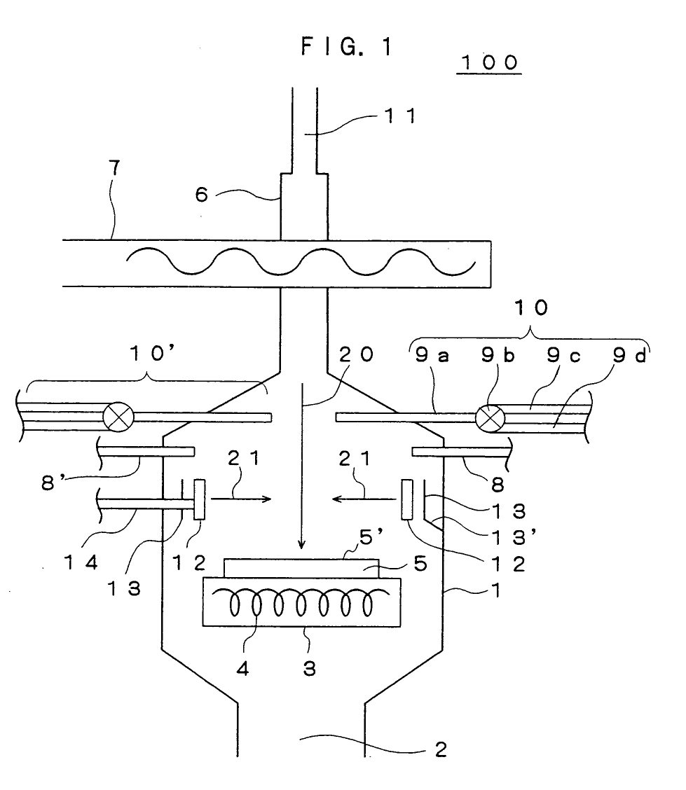

FIG. 1 is a front view showing the schematic configuration of an embodiment of the apparatus for manufacturing a semiconductor of the invention. In FIG. 1, numeral 1 designates a reactor capable of being exhausted and kept in a state of (substantially) a vacuum, and numeral 2 designates an exhaust vent. Numeral 3 designates a substrate holder, and numeral 4 designates a heater. Numeral 5 designates a substrate, and numeral 5′ designates a film-forming surface of the substrate. Numeral 6 designates a quartz pipe, and numeral 7 designates a microwave waveguide (first plasma generator). Numerals 8 and 8′ designate a gas introduction pipe (secondary gas supply unit). Numeral 9a designates a gas introduction pipe, and numeral 9b designates a valve. Each of numerals 9c and 9d designates a gas pipe, and each of numerals 10 and 10′ designates a secondary gas supply unit. Numeral 11 designates a gas introduction pipe (primary gas supply unit), and numeral 12 designates a cylindrical electrode (second plasma generator) including a capacitive coupling-type radiofrequency electrode. Numeral 13 designates an earth electrode, and numeral 13′ designates an earth wire. Numeral 14 designates an RF (radiofrequency) introduction terminal, and numeral 20 designates the central axis of a gas flow blown perpendicularly onto the surface of the substrate. Numeral 21 designates the direction of electrical discharge, and numeral 100 designates the apparatus for manufacturing a semiconductor.

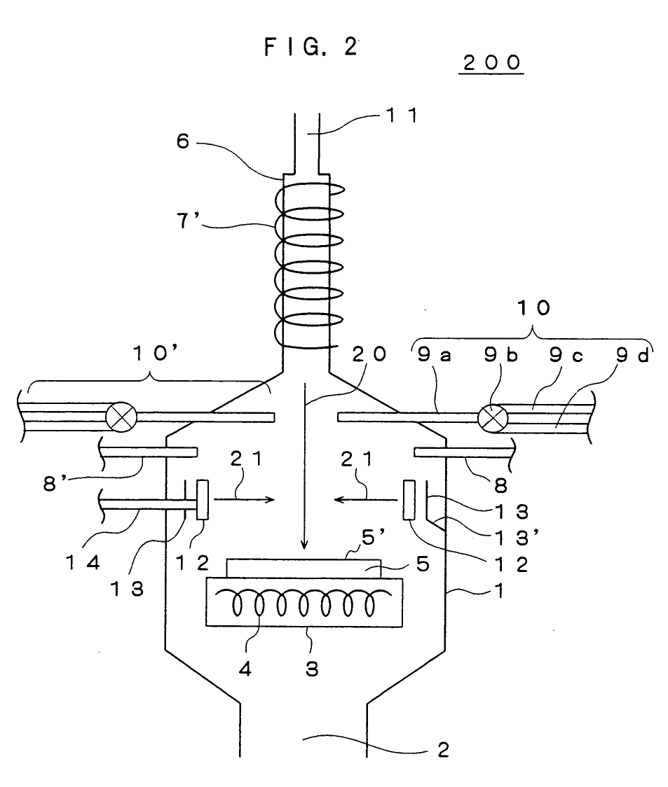

The term “the central axis of the gas flow blown perpendicularly onto the surface of the substrate” is used hereinafter, and the central axis is indicated by an arrow in FIGS. 1 and 2, but this does not mean that the central axis actually exists. The arrow shows the hypothetical center of a region, where the gas is not static and where the gas is flowing most smoothly in one direction, so as to simplify explanation of the drawings.

The apparatus 100 for manufacturing the semiconductor has a substantially cylindrical reactor 1 capable of being kept in a state of vacuum and exhausted. The apparatus 100 also has in the reactor 1 the substrate holder 3 supporting the substrate 5 and including therein the heater 4 to heat the substrate 5. The quartz pipe 6 is connected to the upper portion of the reactor 1 so that the longitudinal direction of the quartz pipe 6 is substantially perpendicular to the surface 5′ of the substrate 5. The exhaust vent 2 is disposed at the lower portion of the reactor 1 on the opposite side of holder 3 to the surface 5′ so that the exhaust vent 2 is substantially perpendicular to the surface 5′. The axial direction of the quartz pipe 6, the axial direction of the reactor 1, the central portion of the substrate holder 3 and the axial direction of the exhaust vent 2 are arranged so as to substantially coincide.

The gas introduction pipe (primary gas supply unit) 11 for introducing a gas into the reactor 1 is connected to an end of the quartz pipe 6 which end is opposite to the other end of the quartz pipe 6 connected to the reactor 1. A unit (not shown) for exhausting gas from the reactor 1 is connected to the reactor 1 via the exhaust vent 2. A microwave waveguide 7, activating gas flowing in the quartz pipe 6 and connected to a micro oscillator (not shown) with a magnetron, is provided near the quartz pipe 6 so that the microwage waveguide 7 intersects perpendicularly with the quartz pipe 6 of the apparatus. The microwave waveguide 7 forms a gas-activating region (a region where microwave waveguide 7 activates raw material gas) in the quartz pipe 6.

Then, in order to form a semiconductor film on the surface 5′, if gas is introduced from the gas introduction pipe 11, through the quartz pipe 6, to supply activated gas into the reactor 1, and at the same time gas supplied into the reactor 1 is exhausted from the exhaust vent 2 then, the gas activated by the microwave waveguide 7 in the quartz pipe 6 flows from the exit of the quartz pipe 6 (the connecting portion of the quartz pipe 6 with the reactor 1) in the direction of the arrow shown by numeral 20, and forms a gas flow blown substantially perpendicularly onto the surface 5′.

A pair of secondary gas supply units 10 and 10′, a pair of gas introduction pipes (secondary gas supply units) 8 and 8′ and the cylindrical electrode (second plasma generator) 12 are arranged substantially symmetrically to the central axis 20 of the gas flow blown substantially perpendicularly onto the surface 5′. The pair of gas introduction pipes 8 and 8′ are disposed under the pair of secondary gas supply units 10 and 10′, and the cylindrical electrode 12 is disposed under the pair of secondary gas supply units 8 and 8′. Moreover the pair of secondary gas supply units 10 and 10′, the pair of gas introduction pipes 8 and 8′, and the cylindrical electrode 12 are disposed at the sidewalls of the reactor 1 between the exit of the quartz pipe 6 and the surface 5′.

Each of the secondary gas supply units 10 and 10′ has: the gas introduction pipe 9a, penetrating the sidewall of the reactor 1; the valve 9b, connected to an external end of the gas introduction pipe 9a; and the two gas pipes 9c and 9d, connected to the valve 9b. Thereby, the gas flowing in the gas pipes 9c and 9d, each connected to a gas supply source (not shown), can be supplied to the reactor 1 via the valve 9b and the gas introduction pipe 9a. Two or more gas pipes may be connected to the valve 9b.

The gas introduction pipe 9a may be a nozzle-like shape with a tapered end portion, closing in towards the end, or may have a trumpet-like shape with an end portion which gradually enlarges. The internal end of the nozzle may be disposed inside or outside a cylindrical region surrounded by a hypothetical surface (not shown) which is obtained by virtually extending the surface of the quartz pipe 6 toward the surface 5′. The gas discharged from the tip of the nozzles can be made to join and to uniformly mix with the gas flow having the central axis 20 by adjusting the position of the tip of the nozzles. Although only a pair of gas introduction pipes (two pipes) 9a are provided in the embodiment shown in FIG. 1, it is preferable that two or more gas introduction pipes are provided. The more gas introduction pipes that are provided, the more preferable that it is. The types, the mixing ratio and the flow rate of gases supplied from the gas introduction pipe 9a to the reactor 1 can be selected or adjusted by the valve 9b having functions of switching the type of gas, mixing gases and adjusting the flow rate of the gases.

Although the gas introduction pipe 9a shown in FIG. 1 has a nozzle-like shape, the nozzle may have a circular or mesh-like tip. A plate for diffusing the gas may be provided at the end of the nozzle so as to make the thickness of the semiconductor thin film formed on the surface 5′ more uniform.

The gas introduction pipes 8 and 8′ disposed on the downstream side of the secondary gas supply units 10 and 10′ may have various configurations and arrangements which are the same as the above-described configurations and arrangements of the secondary gas supply units 10 and 10′, except that the gas introduction pipes 8 and 8′ do not basically have a branched structure. However, it is preferable that the position of the end of the nozzle of the gas introduction pipes 8 and 8′ is disposed outside the electrical discharge region (gas-activating region, region where the cylindrical electrode 12 activates gas flow) of the cylindrical electrode 12, as shown in FIG. 1.

The cylindrical electrode 12 is disposed away from the main stream of the gas flow having the central axis 20, in such a way that the distance of a horizontal line connecting any point on the inner circumferential surface (electrical discharge surface) of the cylindrical electrode 12 and the central axis 20 of the gas flow is kept approximately constant. Therefore, the gas flow passing through the electrical discharge area (gas-activating area) formed by electrical discharge of the cylindrical electrode 12 is almost equally activated in a direction parallel to the surface 5′ of the substrate 5. Thereby, when a semiconductor thin film is formed with the apparatus 100 for manufacturing a semiconductor, the in-plane composition of the semiconductor thin film formed on the surface 5′ can be made more uniform than in a conventional apparatus.

An end of the RF introduction terminal 14 is electrically connected to the outer circumferential surface of the cylindrical electrode 12. The other end of the RF introduction terminal 14 is electrically connected to an RF generation device (not shown) provided outside the reactor 1. In addition, a cylindrical earth electrode 13 is disposed outside the cylindrical electrode 12, and is grounded to the inner wall of the reactor 1 by an earth wire 13.

The apparatus 100 for manufacturing a semiconductor has three gas supply units 8(8′), 11, and 10(10′). However, when forming a semiconductor film, gas containing one or more raw material gases can be supplied to the reactor 1 via one or more gas supply units according to the composition of semiconductor to be deposited and the film deposition conditions.

That is, the raw material gas(es) and the auxiliary gas(es) can be supplied via any of the gas supply units 11, 10, 10′, 8, and 8′ to the reactor 1, depending on the requirements.

However, in order to form a semiconductor thin film whose composition and thickness as a whole are uniform, at least one raw material gas preferably reaches the surface 5′ after passing through two or more gas-activating regions. Therefore, it is preferable that at least one raw material gas is supplied by the primary gas supply unit 11 disposed at the uppermost portion of the apparatus 100.

By doing this, a stable gas flow (gas flow having the central axis 20) blown perpendicularly from the primary gas supply unit 11 onto the surface 5′ can be formed, and the gas is sufficiently activated by the two plasma generators 7 and 12 arranged in series along the gas flow. In addition, by doing this, even when gas is supplied from any of the secondary gas supply units 10, 10′, 8 and 8′, which are arranged in a direction perpendicular to the direction of the gas flow, the flow of the once activated gas is hardly disturbed by the joining of the gas supplied from the horizontal direction, and these gases are sufficiently mixed.

The auxiliary gas(es) used to control the state of activation of the raw material gas and prevent film defects is preferably supplied from the secondary gas supply units 8 and 8′ located near the upper portion of the cylindrical electrode 12.

Even when two or more gases are introduced to the apparatus 100 for manufacturing a semiconductor, these gases are uniformly mixed and form a gas flow which is activated uniformly in the direction parallel to the surface 5′ and which is blown onto the surface 5′. Thereby, a semiconductor thin film having a uniform in-plane thickness and a uniform in-plane composition can be obtained on the surface 5′.

Next, the case in which a nitride semiconductor film of GaInN is produced with the apparatus 100 for manufacturing a semiconductor of the invention will be explained.

First, the substrate 5 is heated to a temperature in the range of about 20 to about 1200° C., and, for instance, nitrogen serving as a raw material is introduced from the gas introduction pipe 11. Microwaves of 2.45 GHz are applied to the microwave waveguide 7 so that the microwave waveguide 7 electrically discharges in the quartz pipe 6. The resulting nitrogen gas is activated in the quartz pipe 6, and then flows into the reactor 1.

At this time, trimethylgallium gas mixed with a carrier gas is introduced from the gas pipe 9c, and trimethylindium gas mixed with a carrier gas is introduced from the gas pipe 9d. These gases are mixed at a desired ratio and the flow rate of the resultant mixed gas is adjusted by the valve 9b. The gas is then introduced from the gas introduction pipe 9a to the reactor 1.

When a raw material gas containing an element of Group III is introduced to the activated nitrogen gas as described above, the activated nitrogen, radicals and ions react with the raw material gas containing the element of Group III, breaking them down and generating activated species.

Also, hydrogen gas serving as the auxiliary gas is introduced from the gas introduction pipe 8. An inert gas such as He or Ar may be introduced as the auxiliary gas instead of the hydrogen gas, as required.

The gases supplied from the three gas supply units merge together to form a gas flow blown perpendicularly onto the surface 5′, and the gas flow is activated by the cylindrical electrode before the gas flow reaches the surface 5′. Thereby, activated elements of Groups III and V, which activated elements are independently controlled, exist in the gas flow immediately before the gas flow reaches the surface 5′. Hydrogen atoms generated by the activation react with the methyl groups of trimethylgallium and trimethylindium to form methane and similar non-active molecules. Thereby, the resultant film does not contain carbon components and film defects are suppressed. A nitride semiconductor thin film which is controlled to the desired composition and with uniform in-plane thickness and composition is formed on the surface 5′.

Next, other embodiments of the apparatus for manufacturing a semiconductor of the invention will be described with reference to the other drawings.

FIG. 2 is a front view showing the schematic configuration of another embodiment of the apparatus for manufacturing a semiconductor of the invention. Numeral 7′ designates a radiofrequency coil (first plasma generator). Numeral 200 designates an apparatus for manufacturing a semiconductor. Members that are the same as those shown in FIG. 1 are represented by the same numerals.

The apparatus for manufacturing a semiconductor shown in FIG. 2 has the same basic configuration as that of the apparatus 100 for manufacturing a semiconductor shown in FIG. 1, except that the microwave waveguide 7 is replaced with the radiofrequency coil 7′, wound around the quartz pipe 6.

Since the apparatus 200 for manufacturing a semiconductor has the same basic configuration as that of the apparatus 100 for manufacturing a semiconductor, the apparatus 200 can form a semiconductor thin film having a uniform in-plane composition and a uniform thickness on the surface 5′.

In the apparatus for manufacturing a semiconductor of the invention shown in FIGS. 1 and 2, electrical discharge of the plasma generators may be AC discharge or DC discharge. In cases of AC discharge, the discharge may be low frequency discharge as well as radiofrequency discharge. In addition, in cases of radiofrequency discharge, the discharge may be induction type discharge or capacity type discharge. An electron cyclotron resonance system or a helicon plasma microwave waveguide may be used in place of the microwave waveguide.

The combination of the first and second plasma generators used in the apparatus for manufacturing a semiconductor of the invention is arbitrary. In other words, the combination is not limited to the combinations shown in FIGS. 1 and 2 of: a microwave waveguide and a capacitive coupling type radiofrequency electrode; and a radiofrequency coil and a capacitive coupling type radiofrequency electrode.

When two or more types of plasma generators are used in one space, it is necessary that these plasma generators simultaneously electrically discharge under the same pressure. Therefore, the pressure in a region where plasma is formed can be made different from that in a region near the substrate, on which a semiconductor is deposited. When the pressure in the region where plasma is formed by the two or more types of generator is made the same, the energy of active species can be varied greatly by using different kinds of plasma generators (for instance, the microwave waveguide 7 and the capacitive coupling type radiofrequency electrode 12 as shown in FIG. 1). Use of different kinds of plasma generators is effective for control of film quality.

The substrate holder 3 may be movable vertically. The substrate holder 3 may be movable between the inside and the outside of the reactor 1 so as to ease setting and removal of the substrate 5. Since the apparatus for manufacturing a semiconductor of the invention can form a semiconductor thin film having a uniform thickness and a uniform in-plane composition, generally it is unnecessary to provide a mechanism for rotating the substrate holder 3 in the plane of the surface 5′. However, when in-plane uniformity of the thickness and composition of the film is more strictly required, such a mechanism may be provided.

The gas introduction pipe 11 is disposed directly above the reactor 1 in the apparatuses 100 and 200, but may be oblique with respect to the axial direction of the quartz pipe 6.

The apparatus for manufacturing a semiconductor of the invention can form a semiconductor thin film on a substrate. However, the apparatus for manufacturing a semiconductor of the invention can be also applied to manufacture of a thin film which can be produced by the MOCVD method and which is other than a semiconductor film.

The Other Embodiments of Second Plasma Generator

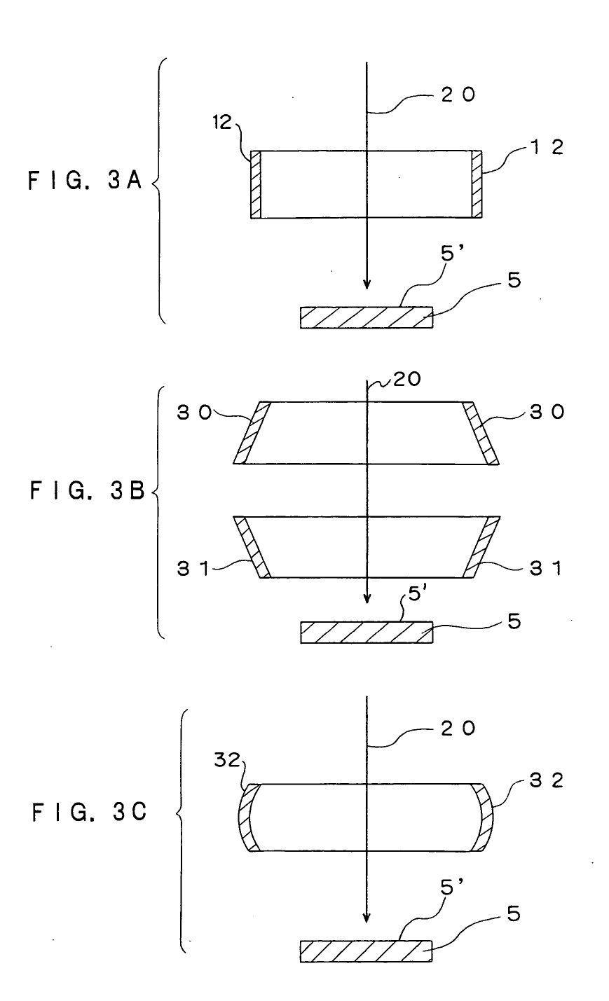

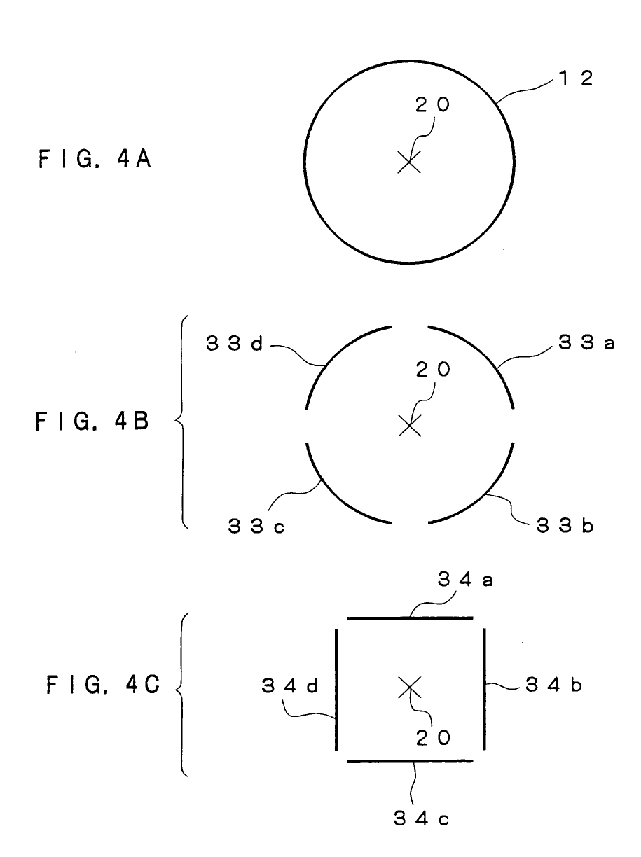

The cylindrical electrode 12 is used as the second plasma generator of the apparatuses shown in FIGS. 1 and 2. However, embodiments of a second plasma generator including plate-shaped electrodes other than the cylindrical electrode will be described with reference to FIGS. 3A to 3C and 4A to 4C. Such a plasma generator is used in apparatuses similar to the apparatuses shown in FIGS. 1 and 2.

FIGS. 3A to 3C are cross-sectional views showing the shapes and arrangements of plate-shaped electrodes (second plasma generator), which cross-sectional views are obtained by cutting the electrodes along a plane parallel to the direction of the gas flow blown perpendicularly onto the surface 5′ of a substrate 5. In FIGS. 3A to 3C, numerals 30, 31, and 32 designate plate-shaped electrodes. The same members as those shown in FIGS. 1 and 2 are represented by the same numerals. The other members such as a reactor and gas supply units are omitted in FIG. 3.

FIG. 3A shows the plate-shaped electrode (cylindrical electrode) 12 shown in FIGS. 1 and 2. The electrical discharge surface thereof is disposed right abeam and arranged parallel to the central axis 20 of the gas flow.

On the other hand, a plate-shaped electrode 30 shown in FIG. 3B may have a discharge surface which faces slightly downstream and which is slightly tilted with respect to the central axis 20 of the perpendicularly blown gas flow. Alternatively, a plate-shaped electrode 31 may have a discharge surface which faces slightly upstream and which is slightly tilted with respect to the central axis 20 of the gas flow.

However, when the discharge surface is excessively tilted with respect to the central axis 20 of the gas flow, the state of activation of the gas flow in the direction parallel to the surface 5′ becomes uneven. Moreover, the in-plane composition of the resultant film may become uneven. For these reasons, an angle between the electrical discharge surface and the central axis 20 of the gas flow is preferably 30 degrees or less, more preferably 20 degrees or less, and most preferably 0 degrees as shown in FIG. 3A.

The plate-shaped electrode is not limited to an electrode having a flat discharge surface, and may have, for example, a curved electrical discharge surface as in a plate-shaped electrode 32 shown in FIG. 3C.

FIGS. 4A to 4C are plane views schematically showing the shapes and arrangements of plate-shaped electrodes (second plasma generator). In FIGS. 4A to 4C, numerals 33a to 33d and 34a to 34d designate plate-shaped electrodes. The same members as those shown in FIGS. 1, 2 and 3A to 3C are represented by the same numerals. The other members such as a reactor and gas supply units are omitted in FIGS. 4A to 4C.

FIG. 4A shows the plate-shaped electrode (cylindrical electrode) 12 shown in FIGS. 1 and 2. One cylindrical electrode 12 is disposed such that the distance of a horizontal line connecting any point on the inner surface of the cylindrical electrode 12 and the central axis 20 of the gas flow is substantially equal.

The electrical discharge surface of the electrode shown in FIG. 4A, disposed such that the distance of a horizontal line connecting any point thereon and the central axis 20 of the gas flow is substantially equal, is the ideal shape. However, when practical viewpoints such as ease of maintenance of the apparatus and simplification of the structure of the apparatus are taken into consideration, one cylindrical electrode may be divided into four parts (electrodes 33a, 33b, 33c, and 33d) as shown in FIG. 3B. Alternatively, four electrodes (electrodes 34a, 34b, 34c, and 34d) having flat discharge surfaces may be used.

In these cases, an earth electrode which is electrically connected to an earth wire, as shown in FIGS. 1, and 2, is disposed outside each of the four electrodes, and an RF (radiofrequency) introduction terminal is electrically connected to the outer surface of each of the four electrodes.

System for Manufacturing a Semiconductor

A system for manufacturing a semiconductor of the invention has one or more apparatus for manufacturing a semiconductor of the invention. More specifically, the system includes a reactor, a substrate holder for supporting a substrate, a unit for moving the substrate holder, and at least two apparatuses for manufacturing a semiconductor. Each apparatus includes: a primary gas supply unit, for supplying a primary gas to the reactor; a secondary gas supply unit, for supplying a secondary gas to the reactor; a first plasma generator, for activating the primary gas to produce an activated gas; and a second plasma generator, for activating a gas flow which includes the activated gas. The gas flow is blown substantially perpendicularly onto the film-forming surface of the substrate, and the second plasma generator electrically discharges toward the center of the gas flow.

Semiconductor thin films (semiconductor layers) having different compositions and desired thicknesses can be laminated with such a system, in the space of a short period of time, using different activation conditions (for instance, different electrical power at the time of electrical discharge, different flow rates of raw material gases and/or different types of doping elements).

The system can consecutively form a film or multi films, avoiding oxidation of the film or multi films caused by the interface(s) between semiconductor layers being exposed to air and contamination caused by particles. Therefore, the system can produce a semiconductor device having high performance and few interface defects.

Moreover, since the system of the invention includes the apparatus of the invention described above, even when semiconductor films to be formed have a large area, each film has a uniform thickness and a uniform in-plane composition. Therefore, even when one wafer in which semiconductor layers are laminated on a large substrate is cut into semiconductor elements, variation in performance of the resultant elements is small and elements having stable quality can be obtained. In addition, a decrease in yield caused by non-uniformity of the in-plane thickness and the in-plane composition of a film, which non-uniformity conventionally tends to easily occur when a wafer to be formed is large, can be suppressed.

There is no particular limitation on the unit for moving the substrate holder. However, the unit is preferably a combination of motor and rail to move the substrate holder on the rail.

Each of the apparatuses of the system can have one reactor, and the reactors are connected to each other via a connecting chamber so that atmosphere is blocked out from the inside of the system. In this case, the substrate holder can be moved in the reactors and the connecting chamber. Each reactor preferably has a gate which can be opened and closed, in order to prevent gas from flowing from one reactor into another reactor by gas diffusion and/or a difference in the internal pressures of the reactors. Controllability of the quality and composition of each semiconductor layer can be further improved by providing such gates on the reactors.

When the composition, quality and deposition conditions of semiconductor layers are similar, the apparatuses of the system of the invention may share one reactor so as to simplify the configuration of the system.

In this case, for instance, a structure can be constructed where two or more sections (film deposition units), each corresponding to the structures above the surface 5′ in the reactor shown in FIG. 1, are disposed around the wall of a cylindrical reactor. In this case, the substrate holder is disposed near, and moved or rotated around the center of the reactor. When semiconductor layers are formed, the substrate holder is first disposed perpendicularly to a gas flow which will flow from one of the sections in the reactor. Then, a first semiconductor layer is formed. Thereafter, the substrate holder is moved or rotated and disposed perpendicularly to another gas flow which will flow from another of the two or more sections, and a second semiconductor layer is laminated on the first semiconductor layer.

1. An apparatus for manufacturing a semiconductor comprising:
a reactor;
a substrate holder for supporting a substrate;
a primary gas supply unit for supplying a primary gas to the reactor;
a secondary gas supply unit for supplying a secondary gas to the reactor;
a first plasma generator for activating the primary gas to produce an activated gas; and
a second plasma generator for activating a gas flow which includes the activated gas;
wherein the gas flow is blown substantially perpendicularly onto a surface of the substrate on which surface a film is to be formed, and the second plasma generator electrically discharges toward the center of the gas flow.

2. The apparatus of claim 1, wherein the second plasma generator is disposed away from a main stream of the gas flow.

3. The apparatus of claim 2, wherein the second plasma generator is a cylindrical electrode surrounding the main stream of the gas flow and having an electrical discharge surface that is disposed substantially parallel to the direction of the gas flow.

4. The apparatus of claim 1, wherein the secondary gas supply unit is disposed such that the secondary gas joins the activated gas between a region where the first plasma generator activates the primary gas and a region where the second plasma generator activates the gas flow.

5. The apparatus of claim 1, wherein the secondary gas supply unit: is disposed outside a region where the second plasma generator activates the gas flow; and enables the secondary gas to join the gas flow in the region and/or upstream of the region.

6. The apparatus of claim 1, wherein the primary gas supply unit has a flow rate adjuster.

7. The apparatus of claim 1, wherein the secondary gas supply unit has a flow rate adjuster.

8. The apparatus of claim 1, comprising two secondary gas supply units.

9. The apparatus of claim 1, wherein the primary gas supply unit is disposed substantially perpendicularly to the surface of the substrate.

10. A system for manufacturing a semiconductor comprising:
a reactor
a substrate holder for supporting a substrate;
a unit for moving the substrate holder; and
at least two apparatuses for manufacturing a semiconductor each comprising,
a primary gas supply unit for supplying a primary gas to the reactor,
a secondary gas supply unit for supplying a secondary gas to the reactor,
a first plasma generator for activating the primary gas to produce an activated gas,
a second plasma generator for activating a gas flow which includes the activated gas, wherein
the gas flow is blown substantially perpendicularly onto a surface of the substrate on which surface a film is to be formed, and
the second plasma generator electrically discharges toward the center of the gas flow.

11. The system of claim 10, wherein each of the at least two apparatuses comprise one reactor, and the at least two reactors are connected to each other so that atmosphere is blocked out from the inside of the system.

12. The system of claim 10, wherein the second plasma generator is disposed away from a main stream of the gas flow.

13. The system for manufacturing a semiconductor of claim 12, wherein the second plasma generator is a cylindrical electrode surrounding the main stream of the gas flow and having an electrical discharge surface which is disposed substantially parallel to the direction of the gas flow.

14. The system of claim 10, wherein the secondary gas supply unit is disposed such that the secondary gas joins the activated gas between a region where the primary plasma generator activates the primary gas and a region where the second plasma generator activates the gas flow.

15. The system of claim 10, wherein the secondary gas supply unit: is disposed outside a region where the second plasma generator activates the gas flow; and enables the secondary gas to join the gas flow in the region and/or upstream of the region.

16. The system of claim 10, wherein the primary gas supply unit has a flow rate adjuster.

17. The system of claim 10, wherein the secondary gas supply unit has a flow rate adjuster.

18. The system of claim 10, comprising two secondary gas supply units.

19. The system of claim 10, wherein the primary gas supply unit is disposed substantially perpendicularly to the surface of the substrate.
